(19) United States
(12) Patent Application Publication
(10) Pub. No.: US 2025/0357034 A1
(43) Pub. Date: Nov. 20, 2025

(54) COMMON MODE FILTER

(71) Applicant: TDK Corporation, Tokyo (JP)

(72) Inventors: Takeshi OKUMURA, Tokyo (JP); Hidenori TSUTSUI, Tokyo (JP); Kouji KAWAMURA, Tokyo (JP); Hibiki MIYASAKA, Tokyo (JP); Shouji SHIMADA, Akita (JP); Hiroki SHIBA, Tokyo (JP)

(21) Appl. No.: 19/188,124

(22) Filed: Apr. 24, 2025

(30) Foreign Application Priority Data
May 14, 2024 (JP) 2024-078709

(51) Int. Cl. H01F 17/00; H03H 7/01

(52) U.S. Cl. CPC H01F 17/0013; H03H 7/0153; H01F 2017/0093

(57) ABSTRACT

Disclosed herein is a common mode filter that includes first and second coil patterns stacked to each other and a magnetic body disposed in the inner diameter areas of the first and second coil patterns. The inner diameter area has a shape in which a size thereof in a first direction is larger than a size thereof in a second direction. The inner diameter area includes a first area positioned on one side in the first direction as viewed from a virtual line and a second area positioned on the other side in the first direction as viewed from the virtual line. The magnetic body is disposed offset to the second area side.

### CROSS-REFERENCE TO RELATED APPLICATION

This application claims the benefit of Japanese Patent Application No. 2024-078709, filed on May 14, 2024, the entire disclosure of which is incorporated by reference herein.

### BACKGROUND OF THE ART

### Field of the Art

The present disclosure relates to a common mode filter and, more particularly, to a common mode filter having a plurality of coil patterns stacked one on another through insulating layers.

### Description of Related Art

Japanese Patent No. 4,683,071 discloses a chip-type common mode filter having two coil patterns stacked one on another through an insulating layer. In this common mode filter, a magnetic body is disposed in the inner diameter area surrounded by the coil patterns in a plan view (in a stacking direction of the coil patterns).

Such a type of common mode filter is required to have higher common mode attenuation and lower differential insertion loss in a limited planar size.

### SUMMARY

A common mode filter according to an aspect of the present disclosure includes: a first coil pattern spirally wound in a plurality of turns; a second coil pattern stacked on the first coil pattern through an insulating layer and spirally wound in a plurality of turns; and a magnetic body disposed in the inner diameter areas of the first and second coil patterns in a plan view as viewed in the stacking direction. The inner diameter area has a shape in which the size thereof in a first direction is larger than the size thereof in a second direction perpendicular to the first direction. The inner diameter area includes a first area positioned on one side in the first direction as viewed from a virtual line extending in the second direction while passing the center of the inner diameter area and a second area positioned on the other side in the first direction as viewed from the virtual line. The first coil pattern includes a first section positioned on the one side in the first direction as viewed from the virtual line and a second section positioned on the other side in the first direction as viewed from the virtual line. The second coil pattern includes a third section positioned on the one side in the first direction as viewed from the virtual line and a fourth section positioned on the other side in the first direction as viewed from the virtual line. The number of coil conductors constituting the first section at at least a part of the circumferential position is larger by one than the number of coil conductors constituting the second section at at least a part of the circumferential position. The number of coil conductors constituting the third section at at least a part of the circumferential position is larger by one than the number of coil conductors constituting the fourth section at at least a part of the circumferential position. The magnetic body is disposed offset to the second area side.

### BRIEF DESCRIPTION OF THE DRAWINGS

The above features and advantages of the present disclosure will be more apparent from the following description of some embodiments taken in conjunction with the accompanying drawings, in which:

FIG. 1 is a schematic perspective view illustrating the outer appearance of a common mode filter 1 according to an embodiment of the technology described herein;

FIG. 2 is a schematic plan view for explaining the pattern shape of the conductor layer 100;

FIG. 3 is a schematic plan view of an insulating layer 10;

FIG. 4 is a schematic plan view for explaining the pattern shape of the conductor layer 200;

FIG. 5 is a schematic plan view of an insulating layer 20;

FIG. 6 is a schematic plan view for explaining the pattern shape of the conductor layer 300;

FIG. 7 is a schematic plan view of an insulating layer 30;

FIG. 8 is an equivalent circuit diagram of the common mode filter 1;

FIG. 9 is a schematic plan view for explaining the pattern shapes of conductor layer 100A according to a modification;

FIG. 10 is a schematic plan view of insulating layer 10A according to a modification;

FIG. 11 is a schematic plan view for explaining the pattern shapes of conductor layer 200A according to a modification;

FIG. 12 is a schematic plan view of insulating layer 20A according to a modification;

FIG. 13 is a schematic plan view for explaining the pattern shapes of conductor layer 300A according to a modification; and

FIG. 14 is a schematic plan view of insulating layer 30A according to a modification.

### DETAILED DESCRIPTION OF THE EMBODIMENTS

The present disclosure relates to a common mode filter having a structure in which a magnetic body is disposed in the inner diameter area surrounded by coil patterns and describes a technology for achieving higher common mode attenuation and lower differential insertion loss.

Some embodiments of the present disclosure will be explained below in detail with reference to the accompanying drawings.

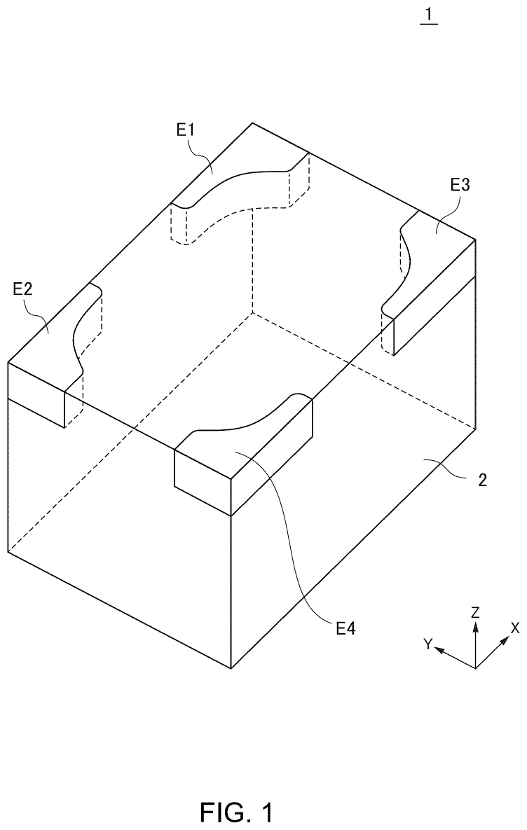

FIG. 1 is a schematic perspective view illustrating the outer appearance of a common mode filter 1 according to an embodiment of the technology described herein.

The common mode filter 1 according to the embodiment is a surface-mount type chip component and includes, as illustrated in FIG. 1, an element body 2 and four terminal electrodes E1 to E4 embedded in the element body 2. As described later, the element body 2 embeds therein three conductor layers 100, 200, and 300 which are stacked one on another through insulating layers.

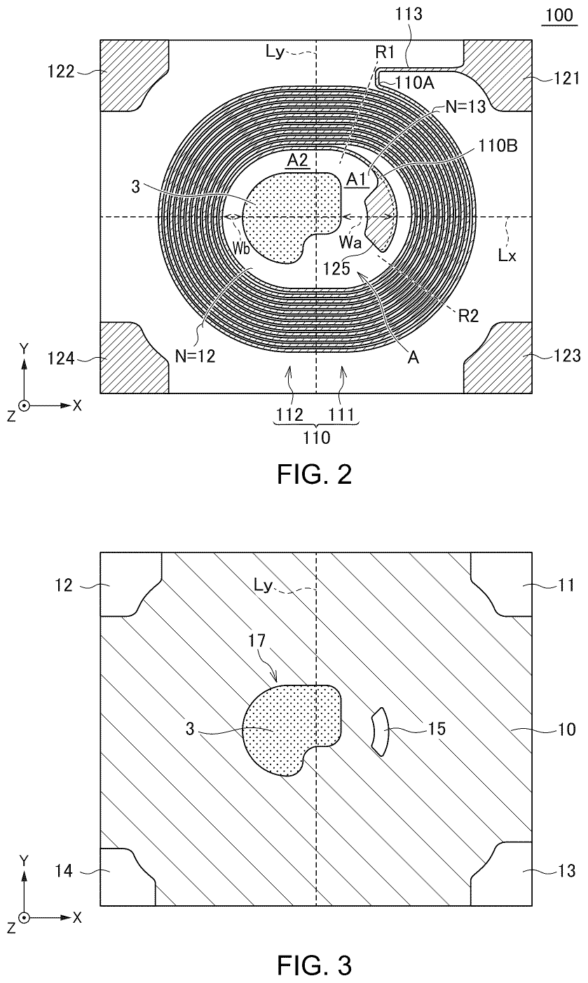

FIG. 2 is a schematic plan view for explaining the pattern shape of the conductor layer 100.

The conductor layer 100 is the lowermost conductor layer and has a spiral coil pattern 110 and connection patterns 121 to 125. An outer peripheral end 110A of the coil pattern 110 is connected to the connection pattern 121 through a lead-out part 113. An inner peripheral end 110B of the coil pattern 110 is connected to the connection pattern 125. The connection pattern 125 can be regarded as a part of the coil pattern 110 and, in this case, the leading end of the connection pattern 125 constitutes the inner peripheral end of the coil pattern 110. The coil pattern 110 is wound clockwise from the outer peripheral end 110A toward the inner peripheral end 110B, whereas the lead-out part 113 linearly extends in the negative X-direction from the outer peripheral end 110A toward the inner peripheral end 110B without being wound clockwise. The connection patterns 122 to 124 are each independently provided without being connected to other conductor patterns in the conductor layer 100.

The coil pattern 110 has a substantially elliptic shape in a plan view (stacking direction, Z-direction) whose long and short axes are in the X-direction and in the Y-direction, respectively. Thus, an inner diameter area A of the coil pattern 110 is larger in size in the X-direction than in the Y-direction. Here, when a virtual line Ly extending in the Y-direction while passing the center of the inner diameter area A of the coil pattern 110 is assumed, the coil pattern 110 is divided into a section 111 positioned on the positive X-direction side as viewed from the virtual line Ly and a section 112 positioned on the negative X-direction side as viewed from the virtual line Ly. As illustrated in FIG. 2, in the present embodiment, both the outer and inner peripheral ends 110A and 110B of the coil pattern 110 belong to the section 111, which means that both the outer and inner peripheral ends 110A and 110B are positioned on the positive X-direction side as viewed from the virtual line Ly. Further, the circumferential position of the inner peripheral end 110B of the coil pattern 110 is ahead of the circumferential position of the outer peripheral end 110A of the coil pattern 110 in the circumferential direction from the outer peripheral end 110A toward the inner peripheral end 110B. This makes the number N (=13) of the coil conductors constituting the section 111 larger by one than the number N (=12) of the coin conductors constituting the section 112.

In the example illustrated in FIG. 2, the number N of the coil conductors is 12 (N=12) at any circumferential position in the section 112. On the other hand, in the section 111, the number N of the coil conductors in an area extending clockwise from a circumferential position R1 to a circumferential position R2 is 13 (N=13), while the number N of the coil conductors in remaining areas is 12 (N=12). The circumferential position R1 is the position of the outer peripheral end 110A of the coil pattern 110. The circumferential position R2 is the position of the clockwise end portion of the connection pattern 125 and corresponds to the inner peripheral end of the coil pattern 110 when the connection pattern 125 is regarded as a part of the coil pattern 110.

The inner diameter area A of the coil pattern 110 is divided into an area A1 positioned on the positive X-direction side as viewed from the virtual line Ly and an area A2 positioned in the negative X-direction as viewed from the virtual line Ly. The connection pattern 125 is entirely positioned in the area A1.

As illustrated in FIG. 2, a magnetic body 3 constituting a part of the element body 2 is disposed in the inner diameter area A of the coil pattern 110. The magnetic body 3 is disposed so as to axially penetrate the inner diameter areas A of the coil patterns 110 and 210. The magnetic body 3 is made of a material higher in permeability than an insulating material, such as resin, constituting the remaining part of the element body 2, an example of which includes a mixture of a resin binder and magnetic filler such as ferrite powder or metal magnetic powder. The magnetic body 3 is not positioned at the center of the inner diameter area A of the coil pattern 110 but is offset to the area A2 side. In the example illustrated in FIG. 2, the virtual line Ly crosses the magnetic body 3 such that a part (large part) of the magnetic body 3 is positioned in the area A2 and the remaining part thereof is positioned in the area A1. Since the magnetic body 3 is disposed offset to the area A2 side, the section 112 of the coil pattern 110 is closer to the magnetic body 3 than the section 111 is.

More specifically, assuming that, in the XY cross section of the magnetic body 3, the area of the magnetic body 3 positioned in the area A1 is Sa, and the area of the magnetic body 3 positioned in the area A2 is Sb, Sa<Sb is satisfied. The area Sb may be equal to or larger than twice the area Sa and may be 2.3 or more times larger than the area Sa. Further, assuming that the Y-direction maximum size of a part of the magnetic body 3 that is positioned in the area A1 is La, and Y-direction maximum size of a part of the magnetic body 3 that is positioned in the area A2 is Lb, La<Lb is satisfied. The size Lb may be 1.2 or more times larger than the size La. Further, a virtual line Lx extending in the X-direction while passing the center of the inner diameter area A of the coil pattern 110 is assumed. In this case, assuming that a distance between a part of the magnetic body 3 that is positioned in the area A1 and the innermost turn of the coil pattern 110 along the virtual line Lx is Wa, and a distance between a part of the magnetic body 3 that is positioned in the area A2 and the innermost turn of the coil pattern 110 along the virtual line Lx is Wb, Wa>Wb is satisfied. The distance Wa may be 1.5 or more times larger than the distance Wb and may be 1.9 or more times larger than the distance Wb. As denoted by the dashed line in FIG. 2, the distance Wa is defined by the distance between a part of the connection pattern 125 that is positioned on the extension of the innermost turn of the coil pattern 110 and the magnetic body 3.

FIG. 3 is a schematic plan view of an insulating layer 10.

The insulating layer 10 is positioned between the conductor layers 100 and 200 and has openings 11 to 15 and 17. The openings 11 to 15 are formed at positions respectively exposing therethrough the connection patterns 121 to 125. The opening 17 is filled with the magnetic body 3.

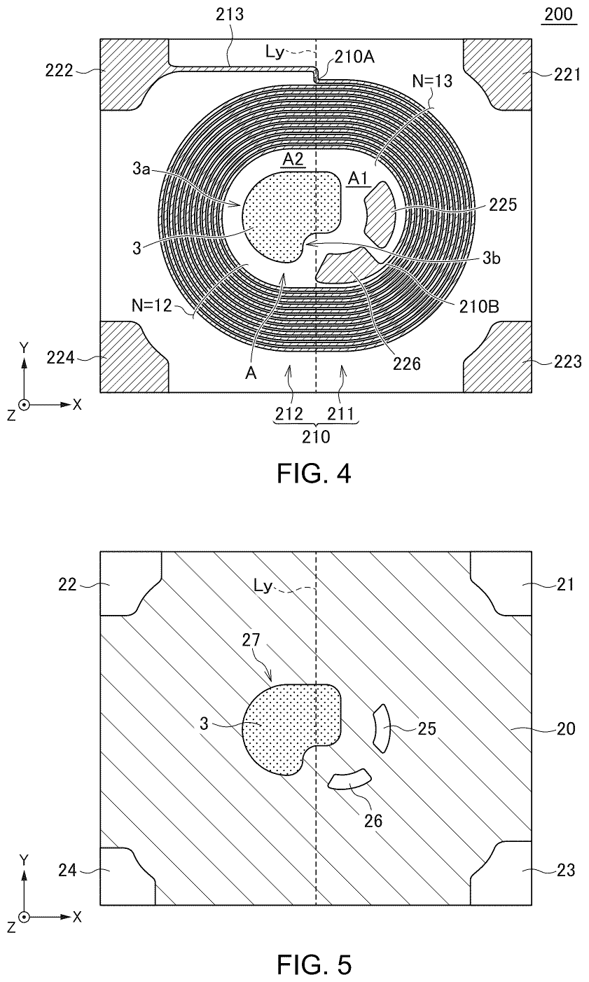

FIG. 4 is a schematic plan view for explaining the pattern shape of the conductor layer 200.

The conductor layer 200 has a spiral coil pattern 210 and connection patterns 221 to 226. An outer peripheral end 210A of the coil pattern 210 is connected to the connection pattern 222 through a lead-out part 213. An inner peripheral end 210B of the coil pattern 210 is connected to the connection pattern 226. The connection pattern 226 can be regarded as a part of the coil pattern 210 and, in this case, the leading end of the connection pattern 226 constitutes the inner peripheral end of the coil pattern 210. The coil pattern 210 is wound clockwise from the outer peripheral end 210A toward the inner peripheral end 210B, whereas the lead-out part 213 linearly extends in the positive X-direction from the connection pattern 222 toward the outer peripheral end 210A. The connection patterns 221, 223, 224, and 225 are each independently provided without being connected to other conductor patterns in the conductor layer 200. The connection patterns 221 to 225 are connected respectively to the connection patterns 121 to 125 through the respective openings 11 to 15 formed in the insulating layer 10.

The number of turns of the coil pattern 210 is substantially the same as that of the coil pattern 110, and the turns of the coil pattern 210 overlap their corresponding turns of the coil pattern 110 in the Z-direction. In order to ensure the function as a common mode filter even when there is a difference in the number of turns between the coil patterns 110 and 210 due to the position of the lead-out part, the difference in the number of turns between the coil patterns 110 and 210 may be ½ turns or less.

Here, when a virtual line Ly extending in the Y-direction while passing the center of the inner diameter area of the coil pattern 210 is assumed, the coil pattern 210 is divided into a section 211 positioned on the positive X-direction side as viewed from the virtual line Ly and a section 212 positioned on the negative X-direction side as viewed from the virtual line Ly. As illustrated in FIG. 4, in the present embodiment, the outer peripheral end 210A of the coil pattern 210 is positioned on the virtual line Ly, and the inner peripheral end 210B of the coil pattern 210 belongs to the section 211. That is, the inner peripheral end 210B of the coil pattern 210 is positioned on the positive X-direction side as viewed from the virtual line Ly. Further, the circumferential position of the inner peripheral end 210B of the coil pattern 210 is ahead of the circumferential position of the outer peripheral end 210A of the coil pattern 210 in the circumferential direction from the outer peripheral end 210A toward the inner peripheral end 210B. This makes the number N (=13) of the coil conductors constituting the section 211 larger by one than the number N (=12) of the coin conductors constituting the section 212.

In the example illustrated in FIG. 4, the number N of the coil conductors is 13 (N=13) at any circumferential position in the section 211, and the number N of the coil conductors is 12 (N=12) at any circumferential position in the section 212. The clockwise end portion of the connection pattern 226 is positioned on the virtual line Ly and corresponds to the inner peripheral end of the coil pattern 210 when the connection pattern 226 is regarded as a part of the coil pattern 210. The connection patterns 225 and 226 are entirely positioned in the area A1.

The position of the magnetic body 3 in the inner diameter area of the coil pattern 210 is the same as that illustrated in FIG. 2. That is, the magnetic body 3 is disposed offset to the area A2 side. As a result, the section 212 of the coil pattern 210 is closer to the magnetic body 3 than the section 211 is.

As illustrated in FIG. 4, the outer peripheral edge of the magnetic body 3 in a plan view (stacking direction, Z-direction) includes a convex edge 3a positioned in the area A2 and extending along the innermost turn of the coil pattern 210 and a concave edge 3b extending so as to avoid the connection pattern 226 constituting the inner peripheral end of the coil pattern 210. The concave edge 3b crosses the virtual line Ly.

FIG. 5 is a schematic plan view of an insulating layer 20.

The insulating layer 20 is positioned between the conductor layers 200 and 300 and has openings 21 to 27. The openings 21 to 26 are formed at positions respectively exposing therethrough the connection patterns 221 to 226. The opening 27 is filled with the magnetic body 3.

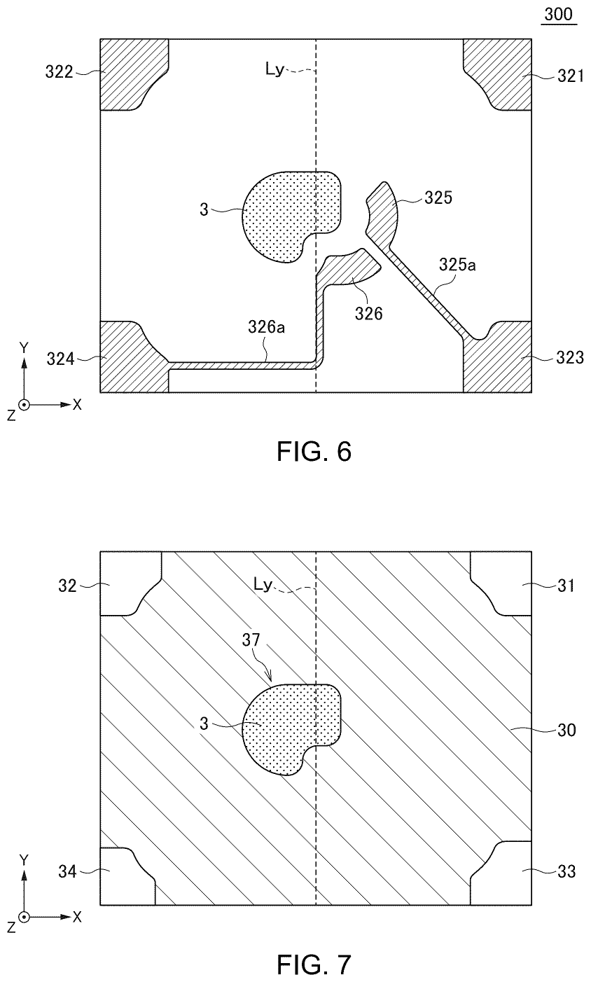

FIG. 6 is a schematic plan view for explaining the pattern shape of the conductor layer 300.

The conductor layer 300 has connection patterns 321 to 326. The connection patterns 321 to 326 are connected respectively to the connection patterns 221 to 226 through the respective openings 21 to 26 formed in the insulating layer 20. The connection pattern 325 is connected to the connection pattern 323 through a lead-out part 325a. The connection pattern 326 is connected to the connection pattern 324 through a lead-out part 326a.

FIG. 7 is a schematic plan view of an insulating layer 30.

The insulating layer 30 is the uppermost insulating layer and has openings 31 to 34 and 37. The openings 31 to 34 are formed at positions respectively exposing therethrough the connection patterns 321 to 324. The opening 37 is filled with the magnetic body 3. The terminal electrodes E1 to E4 illustrated in FIG. 1 are connected respectively to the connection patterns 321 to 324 through the respective openings 31 to 34.

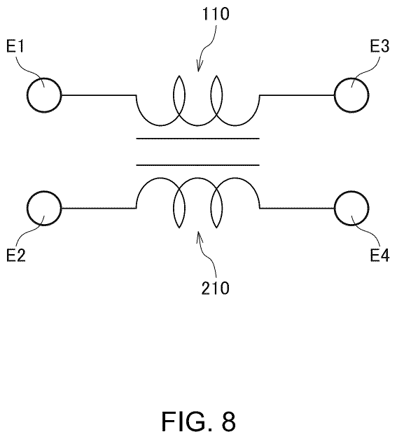

With the above configuration, the outer peripheral end of the coil pattern 110 is connected to the terminal electrode E1, the outer peripheral end of the coil pattern 210 is connected to the terminal electrode E2, the inner peripheral end of the coil pattern 110 is connected to the terminal electrode E3, and the inner peripheral end of the coil pattern 210 is connected to the terminal electrode E4. As a result, as illustrated in FIG. 8, the coil pattern 110 connected between the terminal electrodes E1 and E3 and the coil pattern 210 connected between the terminal electrodes E2 and E4 are coupled to each other.

In addition, in the common mode filter 1 according to the present embodiment, the magnetic body 3 is not disposed at the center of the inner diameter areas of the coil patterns 110 and 210 but is offset to the area A2 side, so that inductance in the sections 112 and 212 having a smaller number of the coil conductors is increased. That is, a difference between inductance generated in the sections 112 and 212 having a smaller number of the coil conductors and inductance generated in the sections 111 and 211 having a larger number of the coil conductors is reduced. As a result, it is possible to achieve higher common attenuation and lower differential insertion loss.

Further, the connection patterns 125, 225, and 226 are disposed in the area A1, allowing effective use of the inner diameter areas A of the coil patterns 110 and 210. That is, the inner diameter areas A of the coil patterns 110 and 210 each have a shape elongated in the X-direction, and the connection patterns 125, 225, and 226 are disposed in a space on the positive X-direction side formed by offsetting of the magnetic body 3 to the negative X-direction, whereby it is possible to dispose the magnetic body 3 and connection patterns 125, 225, and 226 within the inner diameter areas A of the coil patterns 110 and 210 without enlarging the size of the coil patterns 110 and 210.

Furthermore, the magnetic body 3 does not have a simple circular or rectangular planar shape but is formed into a shape having the convex edge 3a in the area A2 and the concave edge 3b at a portion in the vicinity of the connection pattern 226, so that it is possible to further increase the volume of the magnetic body 3 while ensuring a planar distance between the magnetic body 3 and the connection patterns 125, 225, and 226. In addition, the leading end of the connection pattern 226 is positioned substantially on the virtual line Ly, whereby the number of turns of the coil pattern 210 is ensured to the maximum extent. As a result, the concave edge 3b of the magnetic body 3 crosses the virtual line Ly.

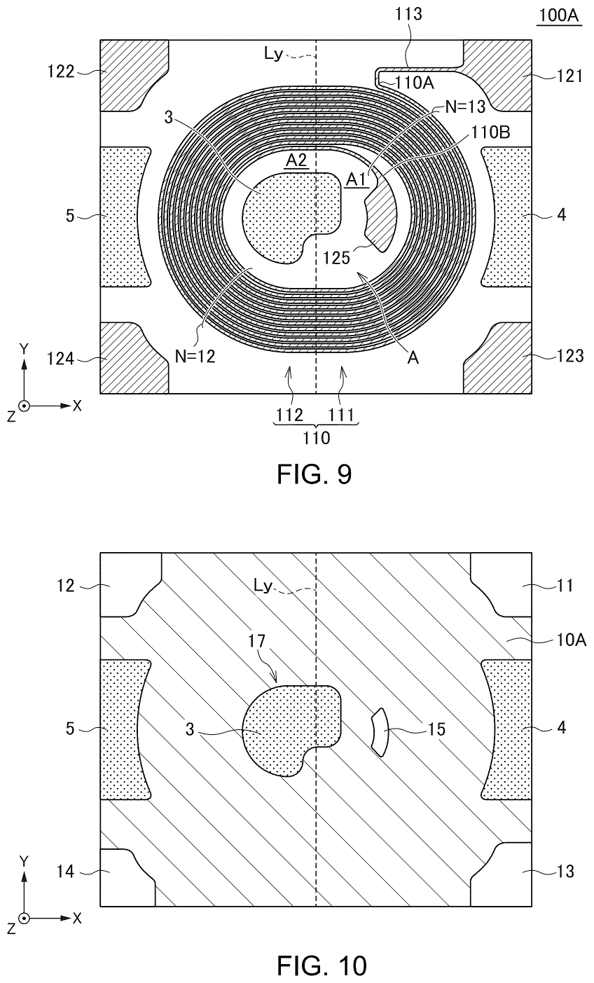

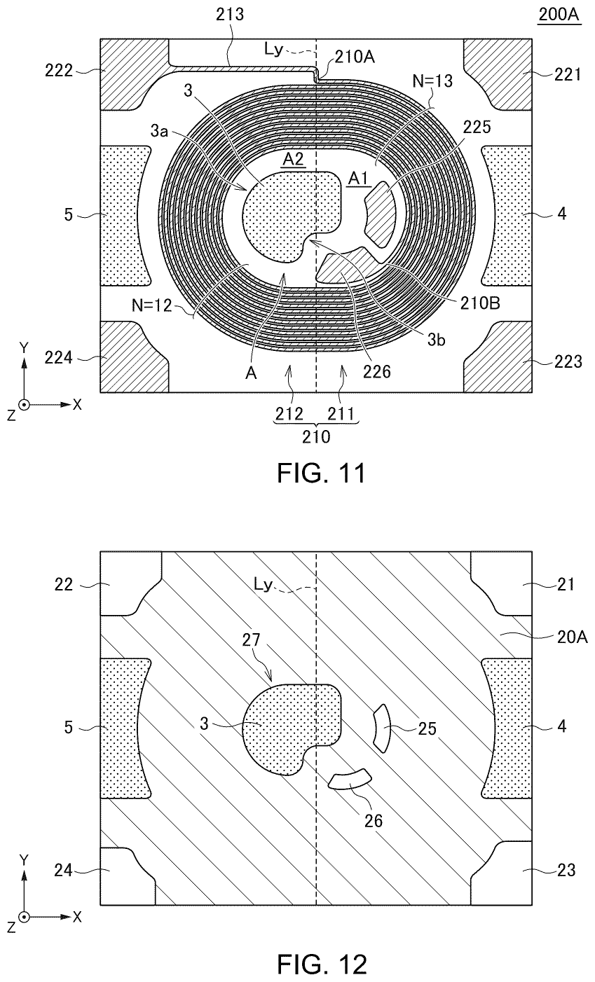

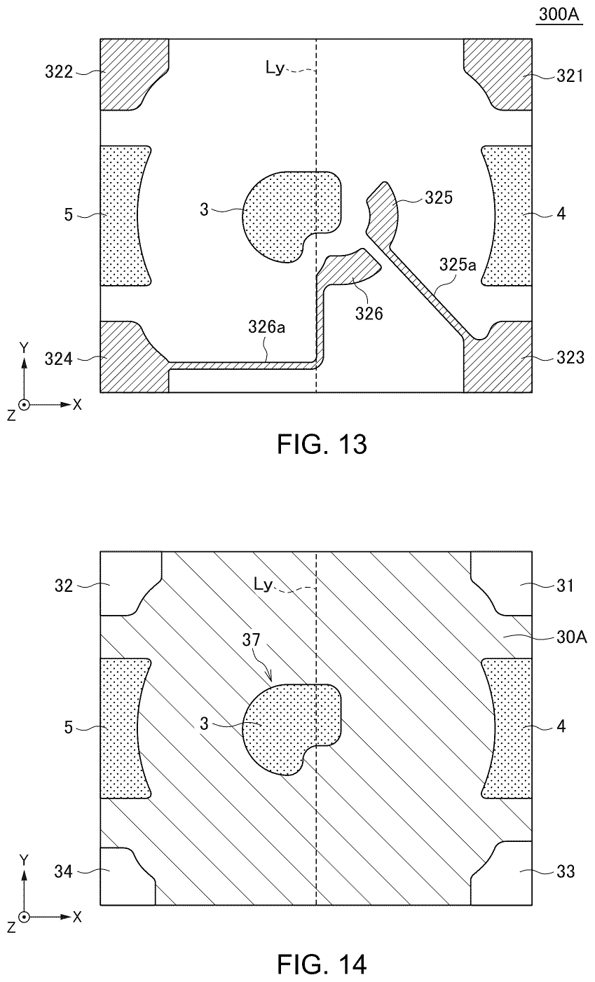

FIGS. 9, 11, and 13 are schematic plan views for explaining the pattern shapes of conductor layers 100A, 200A, and 300A according to a modification. FIGS. 10, 12, and 14 are schematic plan views of insulating layers 10A, 20A, and 30A according to the modification.

The modification illustrated in FIGS. 9 to 14 differs from the configuration illustrated in FIGS. 2 to 7 in that it additionally has magnetic bodies 4 and 5 positioned outside the coil patterns 110 and 210. The magnetic bodies 4 and 5 may each be another part of the element body 2 and made of the same magnetic material as that of the magnetic body 3. Other basic configurations are the same as those of the configuration illustrated in FIGS. 2 to 7, so the same reference numerals are given to the same elements, and overlapping description will be omitted.

The magnetic body 4 is positioned outside the coil patterns 110 and 210 and on the positive X-direction side of the coil patterns 110 and 210. The magnetic body 5 is positioned outside the coil patterns 110 and 210 and on the negative X-direction side of the coil patterns 110 and 210. Adding the thus configured magnetic bodies 4 and 5 further increases the inductance of the coil patterns 110 and 210. In the present embodiment, the element body 2 has a rectangular planar shape with its longer side and shorter side directions being in the X-direction and Y-direction, respectively, so that, in each of the outside areas of the coil patterns 110 and 210, there is more room for the space on the X-direction side than on the Y-direction side. Thus, by disposing the magnetic bodies 4 and 5, the increase in inductance can be achieved.

While some embodiments of the technology according to the present disclosure have been described, the technology according to the present disclosure is not limited to the above embodiments, and various modifications may be made within the scope of the present disclosure, and all such modifications are included in the technology according to the present disclosure.

The technology according to the present disclosure includes the following configuration examples, but not limited thereto.

A common mode filter according to an aspect of the present disclosure includes: a first coil pattern spirally wound in a plurality of turns; a second coil pattern stacked on the first coil pattern through an insulating layer and spirally wound in a plurality of turns; and a magnetic body disposed in the inner diameter areas of the first and second coil patterns in a plan view as viewed in the stacking direction. The inner diameter area has a shape in which the size thereof in a first direction is larger than the size thereof in a second direction perpendicular to the first direction. The inner diameter area includes a first area positioned on one side in the first direction as viewed from a virtual line extending in the second direction while passing the center of the inner diameter area and a second area positioned on the other side in the first direction as viewed from the virtual line. The first coil pattern includes a first section positioned on the one side in the first direction as viewed from the virtual line and a second section positioned on the other side in the first direction as viewed from the virtual line. The second coil pattern includes a third section positioned on the one side in the first direction as viewed from the virtual line and a fourth section positioned on the other side in the first direction as viewed from the virtual line. The number of coil conductors constituting the first section at at least a part of the circumferential position is larger by one than the number of coil conductors constituting the second section at at least a part of the circumferential position. The number of coil conductors constituting the third section at at least a part of the circumferential position is larger by one than the number of coil conductors constituting the fourth section at at least a part of the circumferential position. The magnetic body is disposed offset to the second area side.

In the above common mode filter, the inner peripheral ends of both the first and second coil patterns may be positioned in the first area. This makes it possible to further increase the volume of the magnetic body while ensuring a planar distance between the inner peripheral ends of the first and second coil patterns and the magnetic body.

In the above common mode filter, the outer peripheral edge of the magnetic body in a plan view as viewed in the stacking direction may include a convex edge positioned in the second area and extending along the innermost turns of the first and second coil patterns and a concave edge extending so as to avoid the inner peripheral end of the second coil pattern. This makes it possible to still further increase the volume of the magnetic body while ensuring a planar distance between the inner peripheral end of the second coil pattern and magnetic body. In this case, the concave edge may cross the virtual line. This makes it possible to increase the number of turns of the second coil pattern.

What is claimed is:

1. A common mode filter comprising:
a first coil pattern spirally wound in a plurality of turns;
a second coil pattern stacked on the first coil pattern through an insulating layer and spirally wound in a plurality of turns; and
a magnetic body disposed in inner diameter areas of the first and second coil patterns in a plan view as viewed in a stacking direction,
wherein the inner diameter area has a shape in which a size thereof in a first direction is larger than a size thereof in a second direction perpendicular to the first direction,
wherein the inner diameter area includes a first area positioned on one side in the first direction as viewed from a virtual line extending in the second direction while passing a center of the inner diameter area and a second area positioned on other side in the first direction as viewed from the virtual line,
wherein the first coil pattern includes a first section positioned on the one side in the first direction as viewed from the virtual line and a second section positioned on the other side in the first direction as viewed from the virtual line,
wherein the second coil pattern includes a third section positioned on the one side in the first direction as viewed from the virtual line and a fourth section positioned on the other side in the first direction as viewed from the virtual line,
wherein a number of coil conductors constituting the first section at at least a part of the circumferential position is larger by one than a number of coil conductors constituting the second section at at least a part of the circumferential position,
wherein a number of coil conductors constituting the third section at at least a part of the circumferential position is larger by one than a number of coil conductors constituting the fourth section at at least a part of the circumferential position, and
wherein the magnetic body is disposed offset to the second area side.

2. The common mode filter as claimed in claim 1, wherein inner peripheral ends of both the first and second coil patterns are positioned in the first area.

3. The common mode filter as claimed in claim 2, wherein an outer peripheral edge of the magnetic body in a plan view as viewed in the stacking direction includes a convex edge positioned in the second area and extending along an innermost turns of the first and second coil patterns and a concave edge extending so as to avoid the inner peripheral end of the second coil pattern.

4. The common mode filter as claimed in claim 3, wherein the concave edge crosses the virtual line.

5. A common mode filter comprising:
a first conductor layer including a first coil pattern having a first inner peripheral end and a first outer peripheral end;
a second conductor layer including:
a second coil pattern having a second inner peripheral end and a second outer peripheral end; and
a connection pattern,
a first terminal electrode connected to the first outer peripheral end;
a second terminal electrode connected to the second outer peripheral end;
a third terminal electrode connected to the first inner peripheral end via the connection pattern;
a fourth terminal electrode connected to the second inner peripheral end; and
a magnetic body,
wherein the first coil pattern and the second coil pattern are shacked to each other such that a first inner diameter area of the first coil pattern overlaps with a second inner diameter area of the second coil pattern,
wherein the magnetic body is disposed so as to penetrate the first inner diameter area of the first coil pattern and the second inner diameter area of the second coil pattern,
wherein each of the first and second inner diameter areas includes a first area positioned on one side in a first direction as viewed from a virtual line extending in a second direction perpendicular to the first direction while passing a center of each of the first and second inner diameter areas and a second area positioned on other side in the first direction as viewed from the virtual line,
wherein the first inner peripheral end of the first coil pattern is disposed on the first area of the first inner diameter area,
wherein the second inner peripheral end of the second coil pattern and the connection pattern are disposed on the first area of the second inner diameter area,
wherein a part of the magnetic body is disposed on the first area of each of the first and second inner diameter areas,
wherein a remaining part of the magnetic body is disposed on the second area of each of the first and second inner diameter areas, and
wherein the remaining part of the magnetic body is greater than the part of the magnetic body.

6. The common mode filter as claimed in claim 5, wherein a size of each of the first and second inner diameter areas in the first direction is larger than a size of each of the first and second inner diameter areas in the second direction.
